(19) United States
(12) Patent Application Publication
(10) Pub. No.: US 2024/0147685 A1
(43) Pub. Date: May 2, 2024

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Wen-Li Chiu, Kaohsiung (TW); Chun-Sheng Liang, Changhua (TW)

(21) Appl. No.: 18/099,245

(22) Filed: Jan. 19, 2023

Related U.S. Application Data
(60) Provisional application No. 63/419,888, filed on Oct. 27, 2022.

(51) Int. Cl. H10B 10/00

(52) U.S. Cl. CPC H10B 10/18; H10B 10/12

(57) ABSTRACT

A semiconductor device structure, along with methods of forming such, are described. The structure includes a first source/drain (S/D) epitaxial feature disposed over a substrate, a second S/D epitaxial feature adjacent the first S/D epitaxial feature, and a hybrid fin disposed between the first and second S/D epitaxial features. The hybrid fin includes a first dielectric material, a second dielectric material disposed on the first dielectric material, a dielectric layer surrounding the first and second dielectric materials, and a high-k dielectric layer disposed in the first and second dielectric materials. The high-k dielectric layer has an upper surface located at a level between a level of an upper surface of the second dielectric material and a level of a lower surface of the second dielectric material.

### CROSS-REFERENCE TO RELATED APPLICATIONS

This application claims priority to U.S. Provisional Application Ser. No. 63/419,888 filed Oct. 27, 2022, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example FinFET device structure, in accordance with some embodiments.

FIGS. 2-6 illustrate cross-sectional side views of a semiconductor device structure at various stages of fabrication, in accordance with some embodiments.

FIG. 7 illustrates a cross-sectional view of a portion of the semiconductor device structure taken along line B-B′ of FIG. 6, in accordance with some embodiments.

FIG. 8 illustrates a cross-sectional side view of the semiconductor device structure at one of various stages of fabrication, in accordance with some embodiments.

FIGS. 9-13 illustrate cross-sectional views of a portion of the semiconductor device structure taken along line B-B′ of FIG. 6, in accordance with some embodiments.

FIG. 14 illustrates a cross-sectional side view of the semiconductor device structure of FIG. 13, in accordance with some embodiments.

FIGS. 15-20 illustrate cross-sectional views of the semiconductor device structure at various stages of fabrication, in accordance with alternative embodiments.

FIGS. 21-23 illustrate cross-sectional views of a portion of the semiconductor device structure taken along line C-C′ of FIG. 20, in accordance with some embodiments.

FIG. 24 illustrates a cross-sectional side view of the semiconductor device structure of FIG. 23, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The semiconductor industry has progressed into nanometer technology process nodes in pursuit of higher device density, higher performance, and lower costs. To realize these improvements, the use of fin field effect transistor (FinFET) devices has been gaining popularity in the semiconductor industry. The present disclosure is directed to, but not otherwise limited to, a method of forming dielectric fins in different regions of a wafer in order to simultaneously optimize device performance and reduce transistor bridging or electrical shorting concerns.

To illustrate the various aspects of the present disclosure, a FinFET fabrication process is discussed below as an example. The FinFET device may be a complementary metal-oxide-semiconductor (CMOS) device including a p-type metal-oxide-semiconductor (PMOS) FinFET device and an n-type metal-oxide-semiconductor (NMOS) FinFET device. The following disclosure will continue with one or more FinFET examples to illustrate various embodiments of the present disclosure, but it is understood that the application is not limited to the FinFET device, except as specifically claimed.

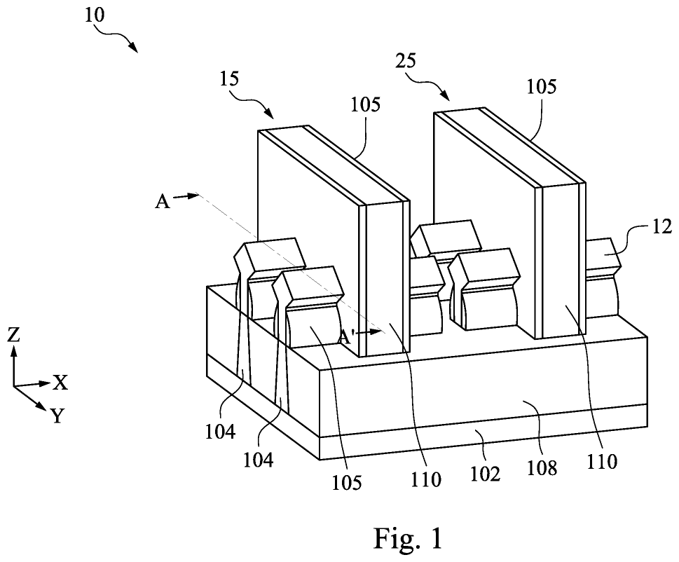

FIG. 1 is a perspective view of an example FinFET device structure 10, in accordance with some embodiments. As shown in FIG. 1, the FinFET device structure 10 includes an NMOS device structure 15 and a PMOS device structure 25. The FinFET device structure 10 includes a substrate 102. The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 may include an epitaxial layer overlying a bulk semiconductor.

The FinFET device structure 10 also includes one or more fin structures 104 (e.g., Si fins) that extend from the substrate 102 in the Z-direction and surrounded by spacers 105 in the Y-direction. The fin structure 104 is elongated in the X-direction and may optionally include germanium (Ge). The fin structure 104 may be formed by using suitable processes such as photolithography and etching processes. In some embodiments, the fin structure 104 is etched from the substrate 102 using dry etch or plasma processes. In some other embodiments, the fin structure 104 can be formed by a double-patterning lithography (DPL) process. DPL is a method of constructing a pattern on a substrate by dividing the pattern into two interleaved patterns. DPL allows enhanced feature (e.g., fin) density. The fin structure 104 also includes an epi-grown material 12, which may (along with portions of the fin structure 104) serve as the source/drain (S/D) of the FinFET device structure 10.

An isolation structure 108, such as a shallow trench isolation (STI) structure, is formed to surround the fin structure 104. In some embodiments, a lower portion of the fin structure 104 is surrounded by the isolation structure 108, and an upper portion of the fin structure 104 protrudes from the isolation structure 108, as shown in FIG. 1. In other words, a portion of the fin structure 104 is embedded in the isolation structure 108. The isolation structure 108 prevents electrical interference or crosstalk.

The FinFET device structure 10 further includes a gate stack structure including a gate electrode 110 and a gate dielectric layer (not shown) below the gate electrode 110. The gate electrode 110 may include polysilicon or metal. Metal includes tantalum nitride (TaN), nickel silicon (NiSi), cobalt silicon (CoSi), molybdenum (Mo), copper (Cu), tungsten (W), aluminum (Al), cobalt (Co), zirconium (Zr), platinum (Pt), or other applicable materials. The gate electrode 110 may be formed in a gate last process (gate replacement process) or a gate first process. The spacers 105 are also formed on sidewalls of the gate electrode 110.

The gate dielectric layer (not shown) may include dielectric materials, such as silicon oxide, silicon nitride, silicon oxynitride, dielectric material(s) with dielectric constant greater than 7 (high-k), or combinations thereof. Examples of high-k dielectric materials include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, the like, or combinations thereof.

In some embodiments, the gate stack structure includes additional layers, such as interfacial layers, capping layers, diffusion/barrier layers, or other applicable layers. In some embodiments, the gate stack structure is formed over a central portion of the fin structure 104. In some other embodiments, multiple gate stack structures are formed over the fin structure 104.

In some embodiments, the gate stack structure is formed in a gate replacement process, and a sacrificial gate stack (not shown) is formed prior to forming the gate stack structure. The sacrificial gate stack may include a sacrificial gate dielectric layer (or the gate dielectric layer), a sacrificial gate electrode, and one or more mask layers. The sacrificial gate stack is formed by a deposition process, a photolithography process and an etching process. The deposition process includes chemical vapor deposition (CVD), physical vapor deposition (PVD), atomic layer deposition (ALD), high density plasma CVD (HDPCVD), metal organic CVD (MOCVD), remote plasma CVD (RPCVD), plasma enhanced CVD (PECVD), plating, other suitable methods, and/or combinations thereof. The photolithography processes include photoresist coating (e.g., spin-on coating), soft baking, mask aligning, exposure, post-exposure baking, developing the photoresist, rinsing, drying (e.g., hard baking). The etching process includes a dry etching process, a wet etching process, or a combination thereof. Alternatively, the photolithography process is implemented or replaced by other proper methods such as maskless photolithography, electron-beam writing, and ion-beam writing.

The sacrificial gate stack may be removed after forming an interlayer dielectric (ILD) over the S/D regions, and the gate stack structure is formed in the space created by the removal of the sacrificial gate stack.

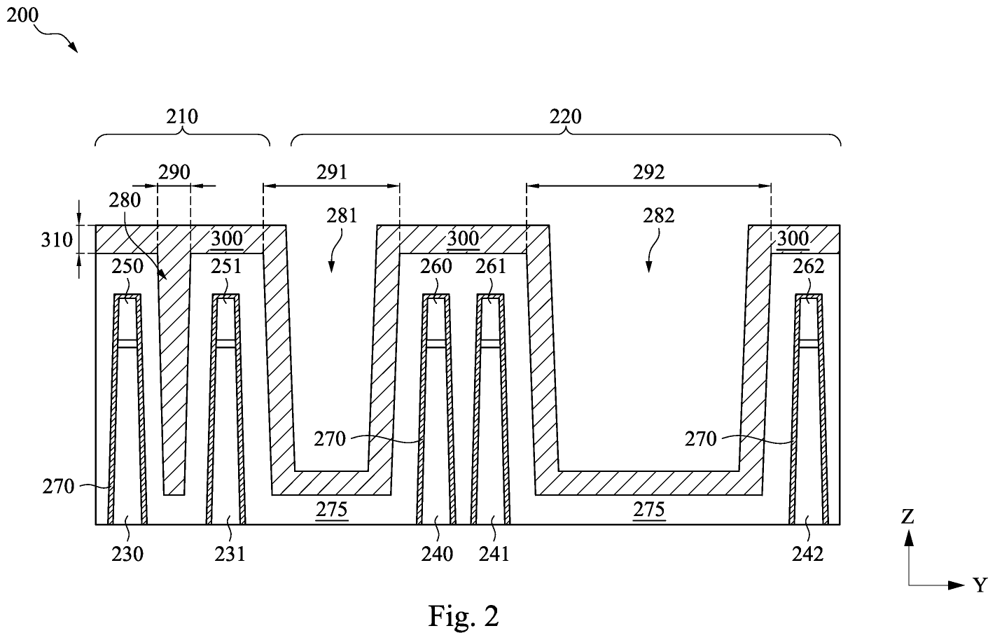

FIGS. 2-6 illustrate cross-sectional side views of a semiconductor device structure 200 at various stages of fabrication, in accordance with some embodiments. As shown in FIG. 2, the semiconductor device structure 200 may be a portion of an IC chip and may include different types of semiconductor devices located in different regions. As an example, the semiconductor device structure 200 includes a memory device region 210 and a logic device region 220. In some embodiments, the memory device region 210 may include Static Random Access Memory (SRAM) devices, and the logic device region 220 may include input/output (I/O) devices or core devices.

It is understood that although the memory device region 210 and the logic device region 220 are illustrated as being disposed adjacent to one another herein, it is not required. In other words, the memory device region 210 and the logic device region 220 may be disposed far apart from one another (or separated by other regions or components) in various embodiments.

Both the memory device region 210 and the logic device region 220 are formed over a substrate (not specifically illustrated herein for reasons of simplicity). The substrate may include a bulk silicon substrate in some embodiments. In other embodiments, the substrate may include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. In further embodiments, the substrate may include a silicon-on-insulator (SOI) substrate. SOI substrates are fabricated using separation by implantation of oxygen, wafer bonding, and/or other suitable methods. In some embodiments, the substrate may be the substrate 102 shown in FIG. 1.

The memory device region 210 and the logic device region 220 may have varying degrees of layout density. For example, the memory device region 210 may have a relatively high layout density, and the spacing between adjacent transistor components may be relatively narrow (e.g., narrower than in the logic device region 220). Conversely, the logic device region 220 may have a relatively low layout density, and the spacing between adjacent transistor components in the logic device region 220 may be greater than in the memory device region 210. Due to the difference in layout density or spacing between components in the regions 210 and 220, the memory device region 210 may be referred to as a dense region, and the logic device region 220 may be referred to as a sparse region. In some embodiments, the pattern density of the memory device region 210 is at least twice as high as the pattern density of the logic device region 220 (e.g., at least twice the number of transistors per unit area).

Both the memory device region 210 and the logic device region 220 include active regions. In some embodiments, the active regions may vertically protrude as a non-planar structure above the substrate (and above isolation features such as STI), for example as fin structures 230-231 in the memory device region 210 and as fin structures 240-242 in the logic device region 220. Similar to the fin structures 104 of FIG. 1, the fin structures 230-231 and 240-242 each extend in an elongated manner horizontally in the X-direction and protrude vertically upwards in the Z-direction. The fin structures 230-231 and 240-242 are also spaced apart from one another in the Y-direction. The fin structures 230-231 and 240-242 may include a semiconductor material such as silicon (Si) or silicon germanium (SiGe), or a III-V group compound such as gallium arsenide (GaAs), indium gallium arsenide (InGaAs), indium phosphide (InP), etc. Some of the fin structures may be n-type fin structures, for example the fin structures 230-231 and 242 may be n-type fin structures. Other fin structures may be p-type fin structures, for example the fin structures 240-241 may be p-type fin structures. It is understood that these are just non-limiting examples. For ease of reference, the fin structures 230-231 and 240-242 may be interchangeably referred to as device fins or active fins hereinafter, to be differentiated from the dielectric fins discussed below.

The fin structures 230-231 and 240-242 may be formed by a patterning process using hard masks 250-251 and 260-262. Each of the hard masks 250-251 and 260-262 patterns one of the fin structures 230-231 and 240-242 below, respectively. The hard masks 250-251 and 260-262 may include a dielectric material. Liners 270 may also be formed on each of the fin structures 230-231 and 240-242. The liners 270 may include a dielectric material such as a low-k dielectric material, silicon oxide, silicon nitride, etc. A dielectric layer 275 is formed over the fin structures 230-231 and 240-242 (and over the liners 270). The dielectric layer 275 may include a dielectric material and may be formed by a deposition process, such as CVD, PVD, ALD, etc. The dielectric layer 275 may serve as an isolation structure such as an STI structure, and it may include a single layer or multiple layers. The dielectric layer 275 may include silicon oxide in some embodiments but may also include other materials in other embodiments. The material composition of the dielectric layer 275 may be configured such that it has an etching selectivity with a subsequently-formed dielectric layer 300 (formed over the dielectric layer 275 and discussed in more detail below). In some embodiments, the dielectric layer 275 may be the isolation structure 108 shown in FIG. 1.

The deposition of the dielectric layer 275 forms trenches in the semiconductor device structure 200, for example trenches 280, 281, and 282 as shown in FIG. 2. The trench 280 may be considered to be formed in the memory device region 210, while the trenches 281-282 may be considered to be formed in the logic device region 220. The trenches 280-282 also have lateral dimensions 290-292 (e.g., measured in the Y-direction), respectively. In some embodiments, each of the dimensions 290-292 may represent the maximum (e.g., the widest) lateral dimension of the respective trench. Due to the different layout densities or spacings between elements in the memory device region 210 and the logic device region 220, the dimension 290 is substantially smaller than the dimensions 291-292. In some embodiments, the dimensions 291 and 292 may each be at least twice as long as the dimension 290.

Still referring to FIG. 2, a dielectric layer 300 is formed in both the memory device region 210 and the logic device region 220. The dielectric layer 300 may be formed by a deposition process such as CVD, PVD, ALD, or combinations thereof. In some embodiments, the dielectric layer 300 has a dielectric constant that is between about 4 and about 10, for example the dielectric layer 300 may include Si₃N₄, SiOCN, SiCN, or other suitable dielectric material. As shown in FIG. 2, due to the differences in the dimensions 290-292, the dielectric layer 300 completely fills the trench 280 in the memory device region 210 but partially fills in the trenches 281-282 in the logic device region 220. This may be achieved by configuring the deposition process parameters (such as process duration) of the dielectric layer 300 such that it has a thickness 310 that is greater than two times the dimension 290. The portion of the dielectric layer 300 filling the trench 280 will form a dielectric fin in the memory device region 210, as discussed below in more detail.

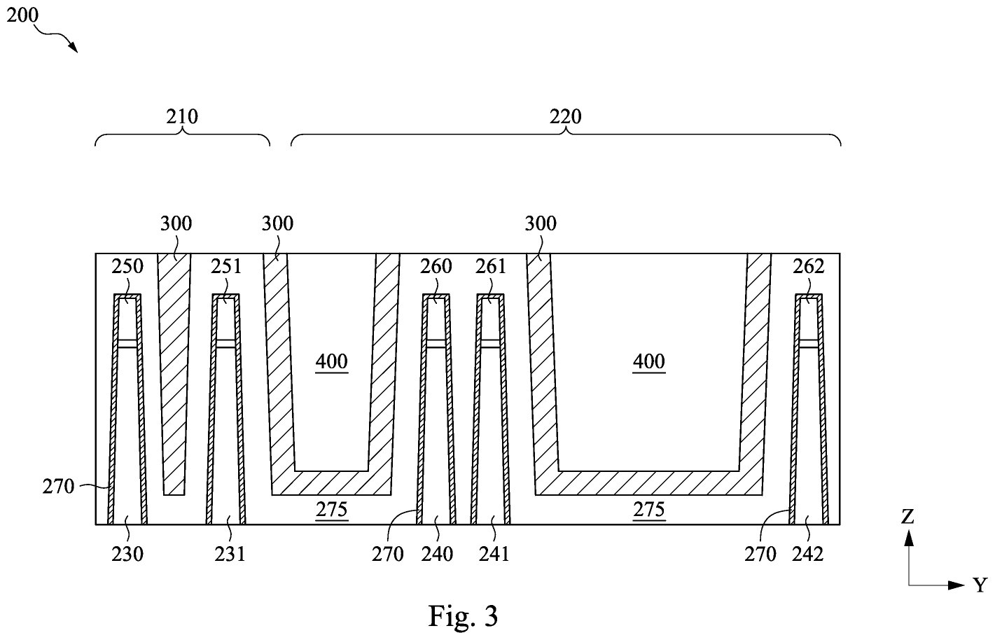

As shown in FIG. 3, a dielectric material 400 is formed on the dielectric layer 300 in the trenches 281-282 and fills the trenches 281-282. In some embodiments, the dielectric material 400 has a dielectric constant less than that of the dielectric layer 300. For example, the dielectric material 400 may be formed using a flowable chemical vapor deposition process (FCVD) and may include a dielectric material having a dielectric less than about 5. For example, the dielectric material 400 may include silicon oxide, which has a dielectric constant slightly less than 4 (e.g., between about 3.7 and about 3.9). In some embodiments, the dielectric material 400 includes plasma-enhanced oxide (PEOX).

Still referring now to FIG. 3, a planarization process is performed to the semiconductor device structure 200 to polish and planarize the dielectric material 400. In some embodiments, the planarization process includes a chemical mechanical polishing (CMP) process. A portion of the dielectric material 400 and a portion of the dielectric layer 300 disposed over the fin structures 230-231, 240-242 are removed until the dielectric layer 275 is exposed. In other words, the dielectric layer 275 serves as a polishing-stop layer for the planarization process. The remaining portions of the dielectric material 400 fill the trenches 281 and 282 and have substantially planar (or flat) upper surfaces, as shown in FIG. 3.

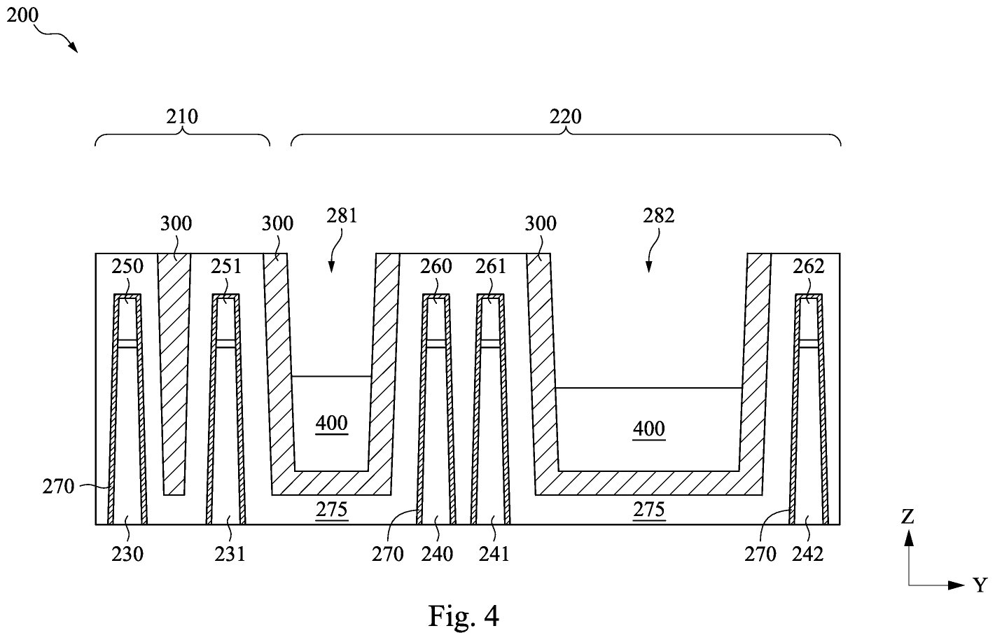

Referring now to FIG. 4, an etch back process is performed to the dielectric material 400. The process parameters of the etch back process are configured such that an etching selectivity exists between the dielectric material 400 and the dielectric layers 300, 275, such that the dielectric material 400 is etched away in a substantially uniform manner while not significantly affecting the dielectric layers 300, 275. The trenches 281, 282 are partially exposed as the result of the etch back process, as shown in FIG. 4. In some embodiments, the dielectric material 400 remaining in the trench 282 has a height substantially less than a height of the dielectric material 400 remaining in the trench 281 as a result of a loading effect.

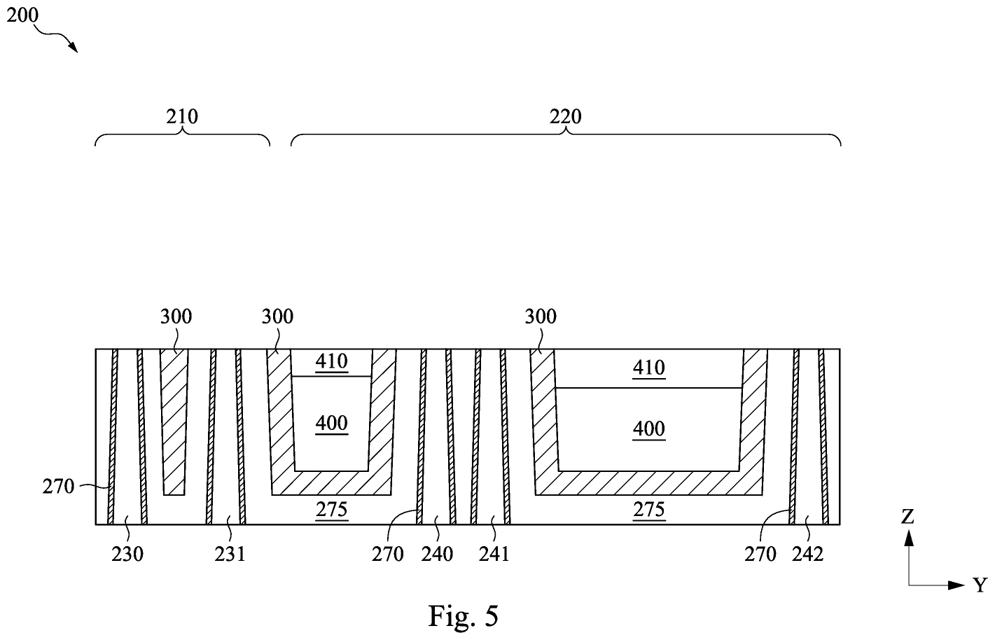

As shown in FIG. 5, a dielectric material 410 is formed on the dielectric material 400 and fills the trenches 281, 282. The dielectric material 410 may include any suitable dielectric material, such as SiN, SiCN, SiOCN. In some embodiments, the dielectric material 410 includes the same material as the dielectric layer 300. In some embodiments, the dielectric material 410 includes a different material from the dielectric layer 300. The term “different material” used herein also covers same materials with different concentrations. A planarization process, such as a CMP process, is performed to polish and planarize various layers located above the fin structures 230-231 and 240-242. Portions of the dielectric material 410, the dielectric layer 275, as well as the hard masks 250-251 and 260-262, are polished and grinded away until the fin structures 230-231 and/or 240-242 are exposed. In other words, the fin structures 230-231 and 240-242 serve as polishing-stop layers for the planarization process. Hence, the planarization process exposes the upper surfaces of the fin structures 230-231 and 240-242, as well as the upper surfaces of the dielectric layers 275, 300 and the dielectric material 410. In some embodiments, the exposed upper surfaces are substantially coplanar.

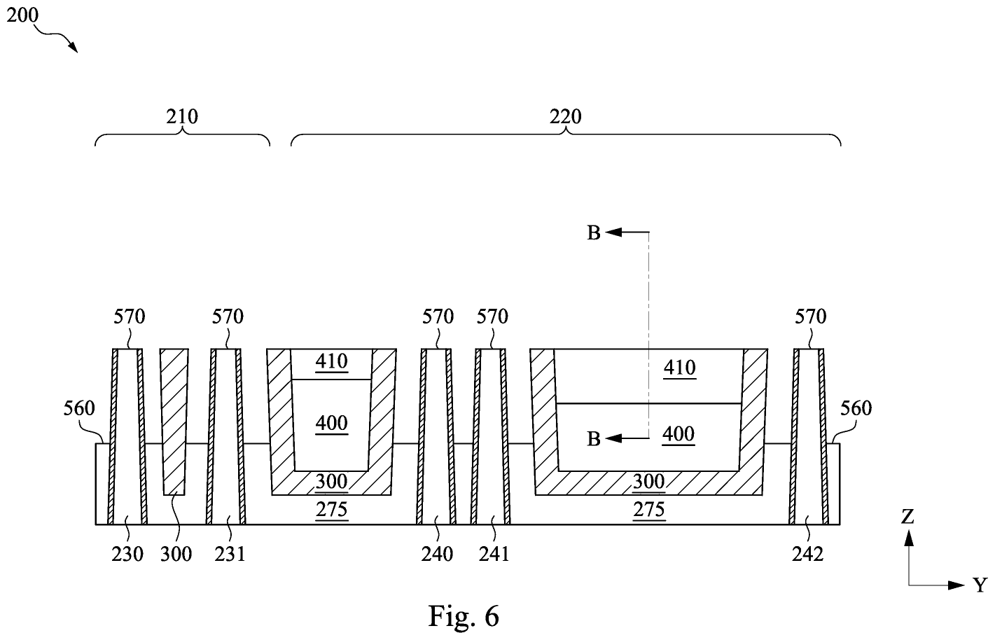

Referring now to FIG. 6, an etching process is performed to recess the dielectric layer 275. In some embodiments, the etching process is performed such that an upper surface 560 of the remaining portion of the dielectric layer 275 is disposed substantially below an upper surface 570 of the fin structures 230-231 and 240-242.

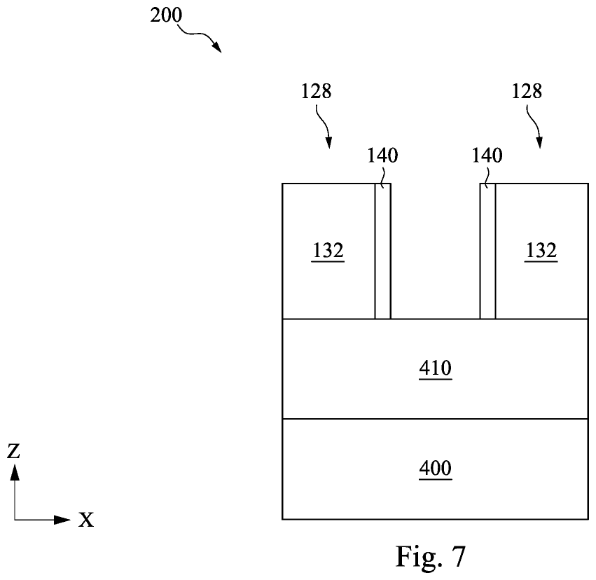

It is understood that FIGS. 2-6 discussed above illustrate a series of cross-sectional views as a “source/drain cut”, meaning that the cross-section in these figures are taken along a portion of the source/drain (e.g., on the portion of the semiconductor device structure 200 corresponding to the cutline A-A′ shown in FIG. 1). To further illustrate the device structure of the present disclosure, FIG. 7 illustrates a cross-sectional view of a portion of the semiconductor device structure 200 taken along line B-B′ of FIG. 6, in accordance with some embodiments.

As shown in FIG. 7, one or more sacrificial gate stacks 128 are formed on one or more portions of the fin structures 230-231, 240-242 and the dielectric material 410. Each sacrificial gate stack 128 may include a sacrificial gate dielectric layer (not shown), a sacrificial gate electrode 132, and a mask structure (not shown). The sacrificial gate dielectric layer may include one or more layers of dielectric material, such as SiO₂, SiN, a high-k dielectric material, and/or other suitable dielectric material. In some embodiments, the sacrificial gate dielectric layer may be deposited by a CVD process, a sub-atmospheric CVD (SACVD) process, a FCVD process, an ALD process, a PVD process, or other suitable process. The sacrificial gate electrode 132 may include polycrystalline silicon (polysilicon). The mask structure may include an oxygen-containing layer and a nitrogen-containing layer. In some embodiments, the sacrificial gate electrode 132 and the mask structure are formed by various processes such as layer deposition, for example, CVD (including both LPCVD and PECVD), PVD, ALD, thermal oxidation, e-beam evaporation, or other suitable deposition techniques, or combinations thereof.

The sacrificial gate stacks 128 may be formed by first depositing blanket layers of the sacrificial gate dielectric layer, the sacrificial gate electrode 132, and the mask structure, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the sacrificial gate stacks 128, the fin structures 230-231, 240-241 are partially exposed on opposite sides of the sacrificial gate stacks 128. Portions of the dielectric material 410 are exposed as a result of the etch process(s) to form the sacrificial gate stacks 128. While two sacrificial gate stacks 128 are shown in FIG. 7, it can be appreciated that they are for illustrative purpose only and any number of the sacrificial gate stacks 128 may be formed.

As shown in FIG. 7, a spacer 140 is formed on each sidewall of the sacrificial gate stacks 128. The spacer 140 may be first conformally deposited on the exposed surfaces of the semiconductor device structure 200. The conformal spacer 140 may be formed by ALD or any suitable processes. An anisotropic etch is then performed on the spacer 140 using, for example, RIE. During the anisotropic etch process, most of the spacer 140 is removed from horizontal surfaces, leaving the spacer 140 on the vertical surfaces, such as on opposite sidewalls of the sacrificial gate stacks 128. The spacers 140 may partially remain on opposite sidewalls of the fin structures 230-231, 240-242. The spacers 140 may be the spacers 105 shown in FIG. 1.

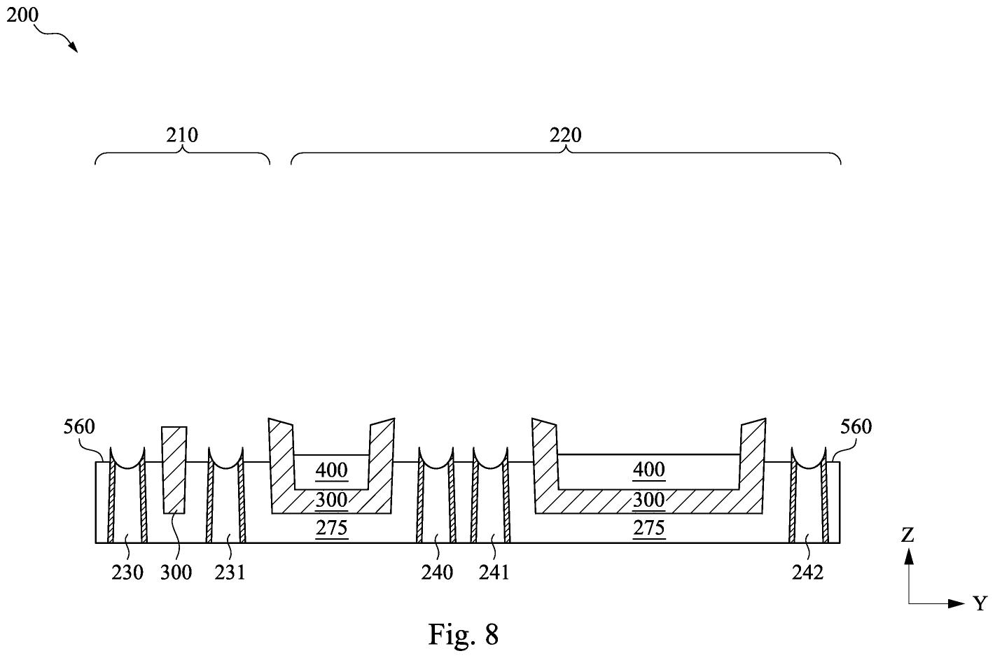

FIG. 8 illustrates a cross-sectional side view of the semiconductor device structure 200 at one of various stages of fabrication, in accordance with some embodiments. As shown in FIG. 8, exposed portions of the fin structures 230-231 and 240-242 not covered by the sacrificial gate stacks 128 are recessed. Source/drain regions will be formed on the remaining portions of the fin structures 230-231 and 240-242. The recessing of the exposed portions of the fin structures 230-231, 240-242 may be performed by one or more etching processes. The one or more etching processes may also remove a portion of the dielectric material 410, a portion of the dielectric layer 300, and a portion of the dielectric material 400, as shown in FIG. 8. In some embodiments, the etch rate of the dielectric layer 300 is substantially slower than the etch rate of the dielectric material 400. As a result, the dielectric material 400 may have an upper surface located at a level substantially below a level of the upper surface of the dielectric layer 300, as shown in FIG. 8.

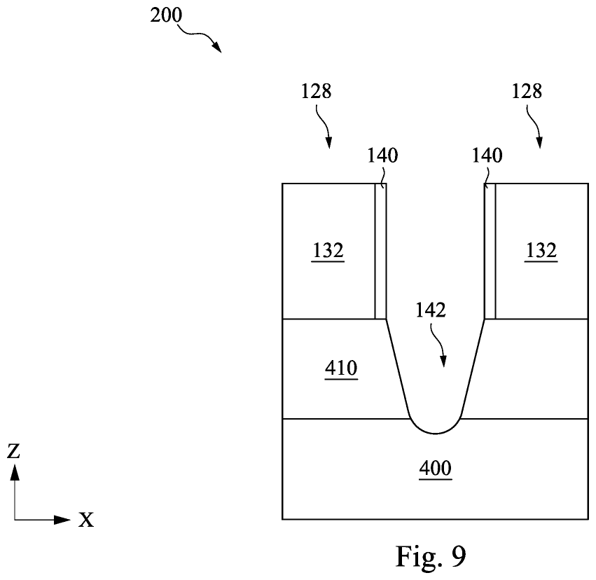

FIGS. 9-13 illustrate cross-sectional views of a portion of the semiconductor device structure 200 taken along line B-B′ of FIG. 6, in accordance with some embodiments. As shown in FIG. 9, which is at the same stage of fabrication as the FIG. 8, an opening 142 is formed in the dielectric material 410 during the recessing the exposed portions of the fin structures 230-231 and 240-242, and the opening 142 extends into the dielectric material 400.

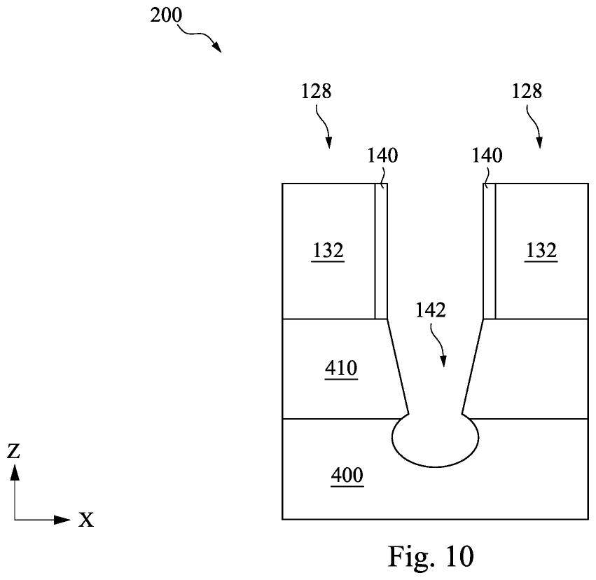

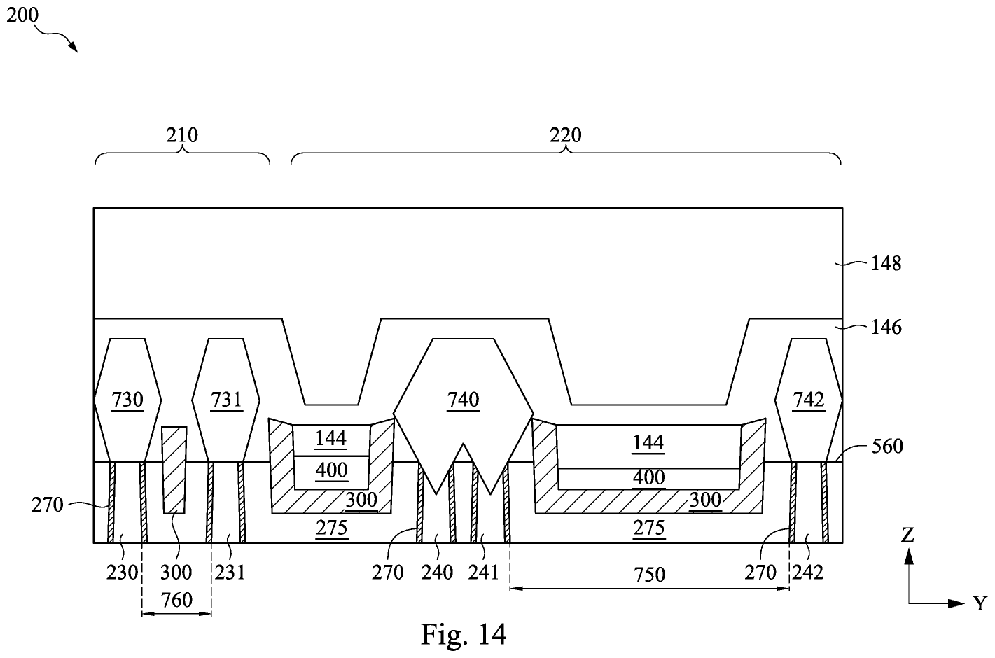

Next, as shown in FIG. 10, the opening 142 is expanded in the dielectric material 400. The expansion of the opening 142 in the dielectric material 400 may be a result of forming the S/D epitaxial features 730-731, 740, and 742 (FIG. 14). As shown in FIG. 14, the S/D epitaxial features 730-731, 740, and 742 may be S/D regions. In this disclosure, a source region and a drain region are interchangeably used, and the structures thereof are substantially the same. Furthermore, source/drain region(s) may refer to a source or a drain, individually or collectively dependent upon the context. The S/D epitaxial features 730-731, 740, and 742 are epitaxially grown on the upper surfaces of the fin structures 230-231, 240-241, and 242, respectively. In some embodiments, the S/D epitaxial features 730-731 and 742 are n-type epitaxial features, and each S/D epitaxial feature 730-731 and 742 may include one or more layers of Si, SiP, SiC, SiCP, SiAs, or a group III-V material (InP, GaAs, AlAs, InAs, InAlAs, InGaAs). Each S/D epitaxial feature 730-731 and 742 may include n-type dopants, such as phosphorus (P), arsenic (As), or other suitable n-type dopants. The S/D epitaxial features 730-731 and 742 may be formed by any suitable method, such as CVD, CVD epitaxy, MBE, or other suitable method. In some embodiments, the S/D epitaxial feature 740 may include one or more layers of Si, SiGe, SiGeB, Ge, or a group III-V material (InSb, GaSb, InGaSb). The S/D epitaxial feature 740 may include p-type dopants, such as boron (B) or other suitable p-type dopants. The S/D epitaxial feature 740 may be formed by any suitable method, such as CVD, CVD epitaxy, MBE, or other suitable method.

As shown in FIG. 14, the S/D epitaxial feature 740 is formed by two epitaxial features that are grown separately on the fin structures 240-242 but that are merged together laterally. The merging of the epitaxial features to form the S/D epitaxial feature 740 may be intentional and desirable in the illustrated embodiment, since these S/D epitaxial features do not need to be electrically isolated, and a larger size of the S/D epitaxial feature 740 may lead to faster logic device performance.

The S/D epitaxial features 730, 731, 742 and the S/D epitaxial feature 740 may be formed at different times using one or more masks (not shown). For example, a first patterned mask is formed to cover the exposed surfaces of the fin structures 240, 241, and the S/D epitaxial features 730, 731, 742 are formed from the exposed surfaces of the fin structures 230, 231, 242, respectively. Then, the first patterned mask is removed, a second patterned mask is formed on the S/D epitaxial features 730, 731, 742 while the fin structures 240, 241 are exposed, and the S/D epitaxial feature 740 is formed from the fin structures 240, 241. The second patterned mask is then removed.

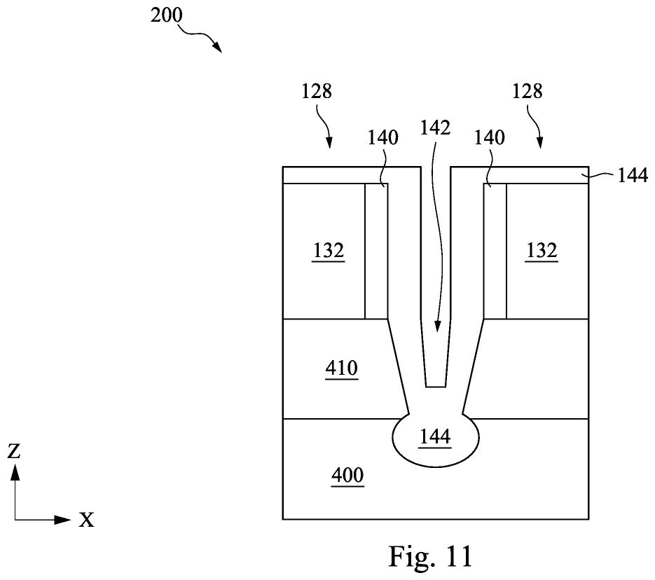

Referring back to FIG. 10, the removal of the first and second patterned mask layers caused the opening 142 to expand in the dielectric material 400. The opening 142 in the dielectric materials 400, 410 may have a “keyhole” shaped cross-section, as shown in FIG. 10. Next, as shown in FIG. 11, after forming the S/D epitaxial features 730, 731, 740, 742, a high-k dielectric layer 144 is formed in the opening 142. The high-k dielectric layer 144 may be also formed on the sidewalls of the dielectric material 410 and the spacers 140, as shown in FIG. 11. The high-k dielectric layer 144 may include an oxide, such as a metal oxide. In some embodiments, the high-k dielectric layer 144 includes hafnium oxide, zirconium oxide, zirconium aluminum oxide, hafnium aluminum oxide, hafnium silicon oxide, aluminum oxide, or the like; combinations thereof; or the like. The high-k dielectric layer 144 may be formed by a conformal process, such as an ALD process. The term “conformal” may be used herein for ease of description upon a layer having substantial same thickness over various regions. The high-k dielectric layer 144 may be also formed on the S/D epitaxial features 730, 731, 740, 742, the dielectric layer 300, the dielectric layer 275, and over the sacrificial gate stacks 128. In some embodiments, the high-k dielectric layer 144 has a thickness ranging from about 5 nm to about 15 nm, such as about 10 nm. The high-k dielectric layer 144 fills the portion of the opening 142 in the dielectric material 400, while the portion of the opening 142 in the dielectric material 410 is partially filled with the high-k dielectric layer 144. If the thickness of the high-k dielectric layer 144 is less than about 5 nm, the portion of the opening 142 in the dielectric material 400 may not be filled. As a result, an air gap may be formed in the high-k dielectric layer 144. On the other hand, if the thickness of the high-k dielectric layer 144 is greater than about 15 nm, the subsequent process to remove portions of the high-k dielectric layer 144 may take longer.

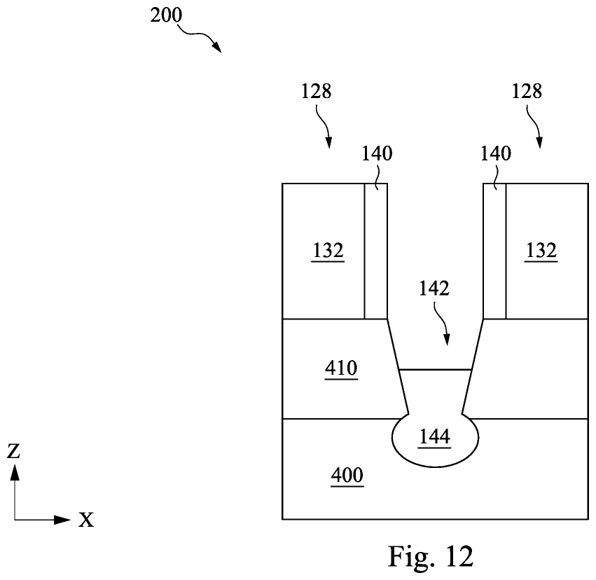

As shown in FIG. 12, portions of the high-k dielectric layer 144 is removed. In some embodiments, the removal of the portions of the high-k dielectric layer 144 is performed by an etch back process. For example, a selective etching process is performed to remove the portions of the high-k dielectric layer 144, such as the portions of the high-k dielectric layer formed on the S/D epitaxial features 730, 731, 740, 742, the dielectric layer 300, the dielectric layer 275, over the sacrificial gate stacks 128, and on the sidewalls of the spacers 140. In some embodiments, the portions of the high-k dielectric layer 144 formed on a portion of the sidewalls of the dielectric material 410 are also removed, as shown in FIG. 12. The etch back process may be controlled so the portion of the high-k dielectric layer 144 formed in the portion of the opening 142 in the dielectric material 400 is not removed. In some embodiments, the remaining portion of the high-k dielectric layer 144 has an upper surface at a level between the level of an upper surface of the dielectric material 410 and the level of a lower surface of the dielectric material 410, as shown in FIG. 12.

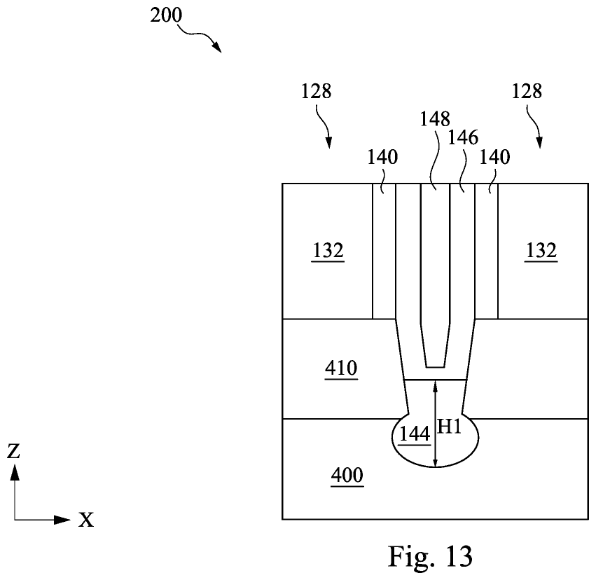

As shown in FIG. 13, a contact etch stop layer (CESL) 146 and an interlayer dielectric (ILD) layer 148 are formed over the remaining high-k dielectric layer 144. The CESL 146 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. The materials for the ILD layer 148 may include compounds comprising Si, O, C, and/or H, such as SiOCH, oxide formed using tetraethylorthosilicate (TEOS), un-doped silicate glass, silicon oxide, or doped silicon oxide such as borophosphosilicate glass (BPSG), fused silica glass (FSG), phosphosilicate glass (PSG), boron doped silicon glass (BSG), and/or other suitable dielectric materials. The ILD layer 148 may be deposited by a PECVD process or other suitable deposition technique. A planarization process may be performed to remove portions of the CESL 146 and the ILD layer 148 formed over the sacrificial gate stacks 128. In some embodiments, the mask structure formed on the sacrificial gate electrode 132 is also removed by the planarization process, and the sacrificial gate electrodes 132 are exposed.

In some embodiments, the high-k dielectric layer 144 is not present, and the CESL 146 is formed in the dielectric material 400. An air gap may be formed in the CESL 146, because the high-k dielectric layer 144 has better gap filling capability compared to the CESL 146. As a result, subsequently formed conductive feature may be formed in the air gap, leading to an electrical leakage path. Thus, by filling the portion of the opening 142 in the dielectric material 400 with the high-k dielectric layer 144, leakage path is minimized.

In some embodiments, the high-k dielectric layer 144 has a height H1 ranging from about 30 nm to about 60 nm, such as about 35 nm. The high-k dielectric layer 144 is seamless and void-free.

FIG. 14 illustrates a cross-sectional side view of the semiconductor device structure 200 of FIG. 13, in accordance with some embodiments. FIG. 14 illustrates the S/D regions of the semiconductor device structure 200. As shown in FIG. 14, the high-k dielectric layer 144 is disposed on the dielectric material 400, and the dielectric layer 300 surrounds the high-k dielectric layer 144 and the dielectric material 400. The CESL 146 is disposed on the S/D epitaxial features 730, 731, 740, 742, the dielectric layer 300, and the high-k dielectric layer 144. The dielectric layer 300, the dielectric materials 400, 410, and the high-k dielectric layer 144 may be a hybrid fin or a dielectric fin.

In subsequent processes, conductive features (not shown) are formed in the ILD layer 148 and the CESL 146 to be electrically connected to the S/D epitaxial features 730, 731, 740, 742. In some embodiments, the process window for forming the openings in the ILD layer 148 and the CESL 146 may be large, such that the portions of the ILD layer 148 and the CESL 146 formed over the high-k dielectric layer 144 are removed. Because the high-k dielectric layer 144 is seamless and void-free, and the high-k dielectric layer 144 and the CESL 146 have substantially different etch selectivity, the conductive features are not formed in the high-k dielectric layer 144. As a result, the formation of leakage path is substantially reduced.

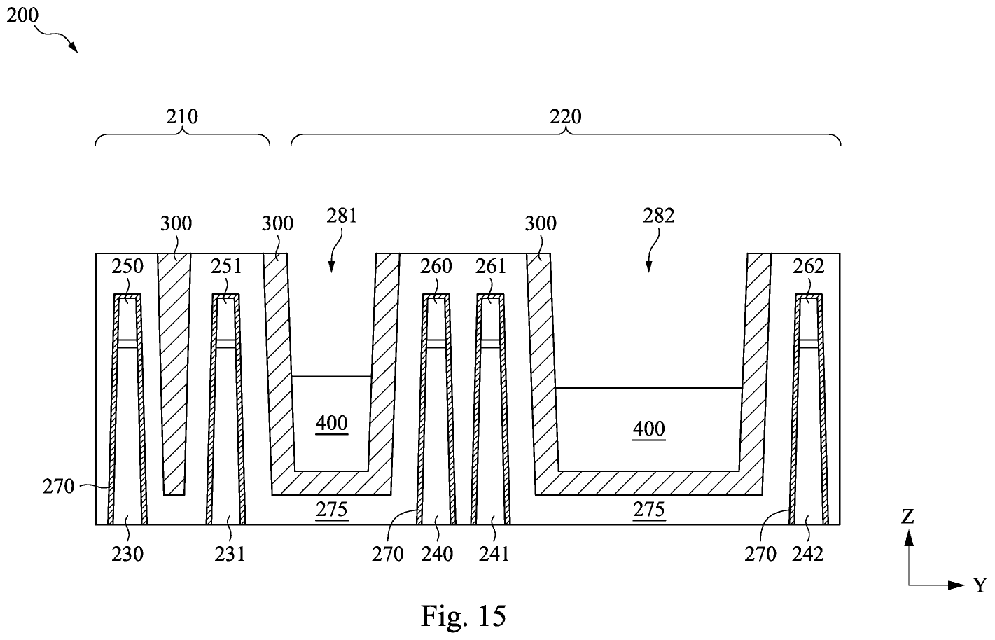

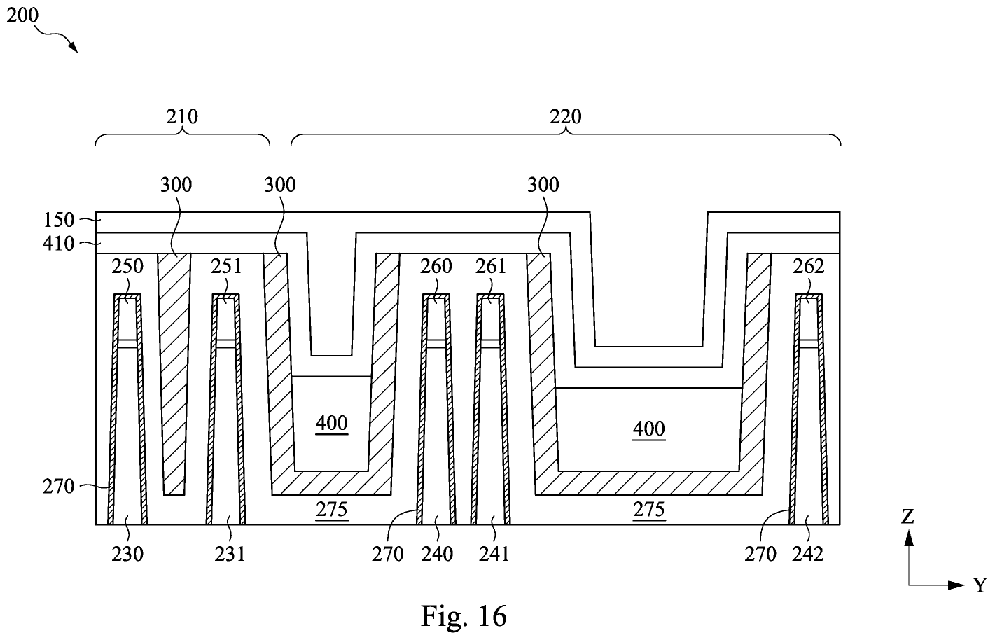

FIGS. 15-20 illustrate cross-sectional views of the semiconductor device structure 200 at various stages of fabrication, in accordance with alternative embodiments. As shown in FIG. 15, which may be at the same fabrication stage as in FIG. 4, the dielectric material 400 is deposited and recessed in the trenches 281, 282. Next, as shown in FIG. 16, the dielectric material 410 is deposited on the dielectric material 400 in the trenches 281, 282. The dielectric material 410 may be also deposited over the fin structures 230, 231, 240, 241, 242. A high-k dielectric layer 150 is deposited on the dielectric material 410. The high-k dielectric layer 150 may include the same material as the high-k dielectric layer 144 and may be formed by the same process as the high-k dielectric layer 144. In some embodiments, the high-k dielectric layer 150 fills the trench 281 but not the trench 282. The high-k dielectric layer 150 may have a thickness ranging from about 5 nm to about 15 nm, such as about 10 nm.

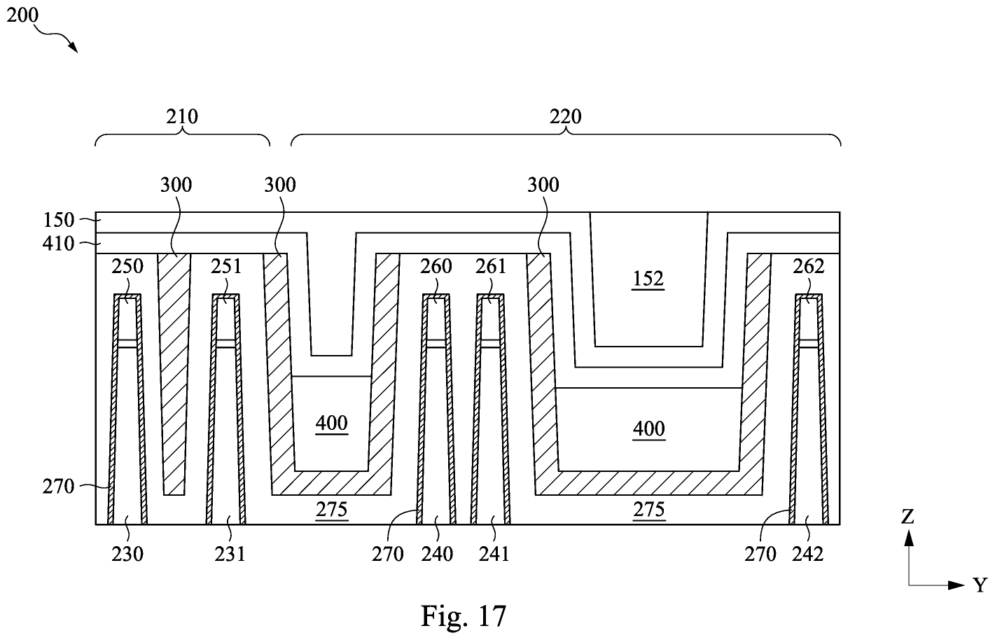

Next, as shown in FIG. 17, a dielectric material 152 is deposited in the opening 282 to fill the opening 282. The dielectric material 152 may be also deposited over the fin structures 230, 231, 240, 241, 242, and a planarization process may be performed to remove the portions of the dielectric material 152 formed over the fin structures 230, 231, 240, 241, 242, as shown in FIG. 17. The dielectric material 152 may include the same material as the dielectric material 400 and may be formed by the same process as the dielectric material 400.

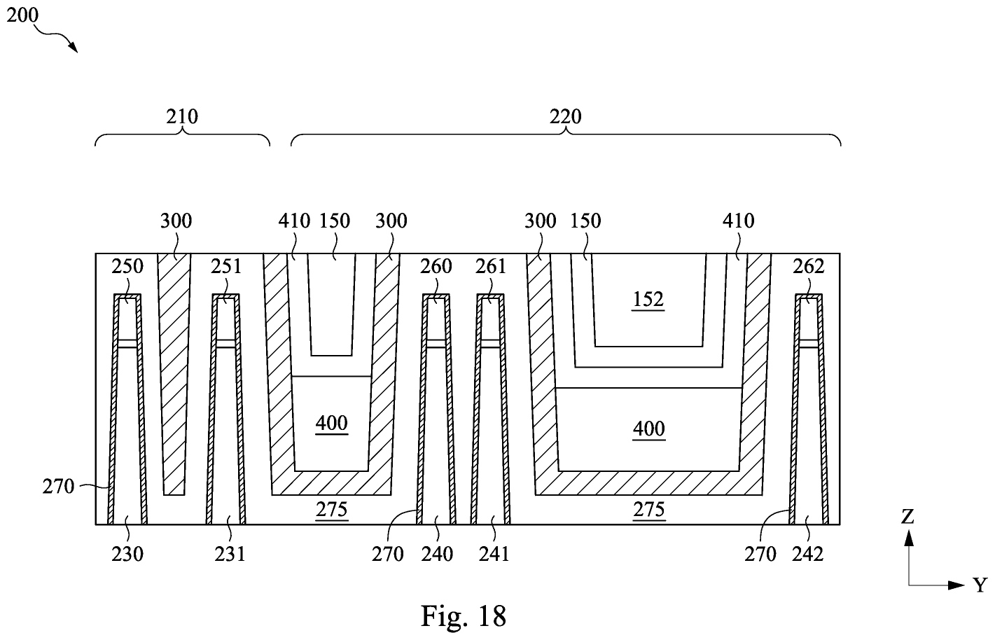

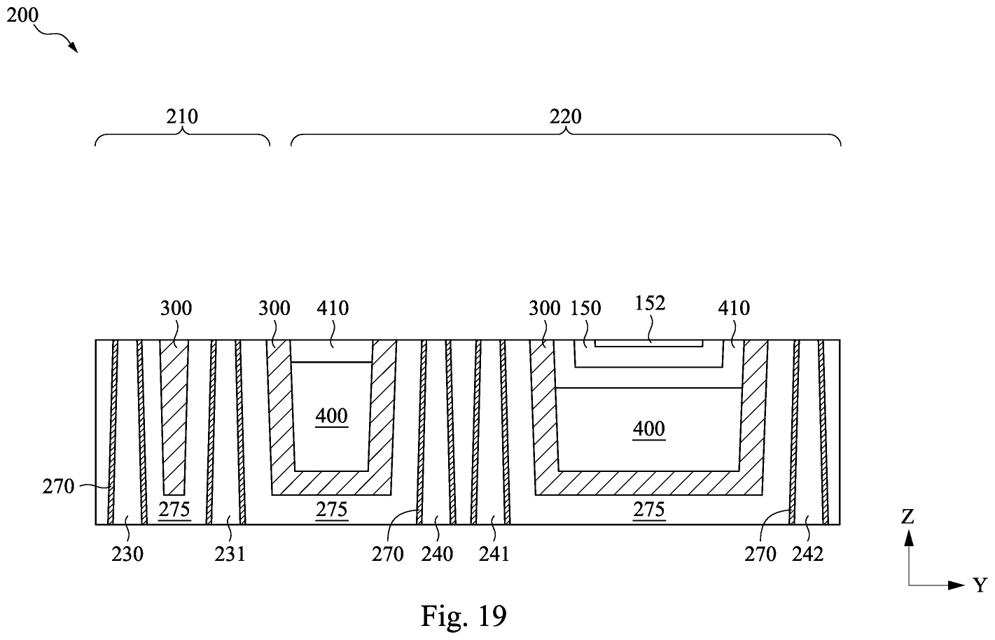

As shown in FIG. 18, a planarization process is performed to remove a portion of the high-k dielectric layer 150, a portion of the dielectric material 410, and a portion of the dielectric material 152 until the dielectric layer 275 is exposed. In other words, the dielectric layer 275 serves as a polishing-stop layer for the planarization process. Next, another planarization process is performed to expose the fin structures 230, 231, 240, 241, 242, as shown in FIG. 19. As a result of the second planarization process, different materials are disposed between the fin structures 231, 240 and between the fin structures 241, 242. For example, the dielectric layer 300 and the dielectric materials 400, 410 are disposed between the fin structures 231, 240, and the dielectric layer 300, the dielectric materials 400, 410, 152, and the high-k dielectric layer 150 are disposed between the fin structures 241, 242, as shown in FIG. 19.

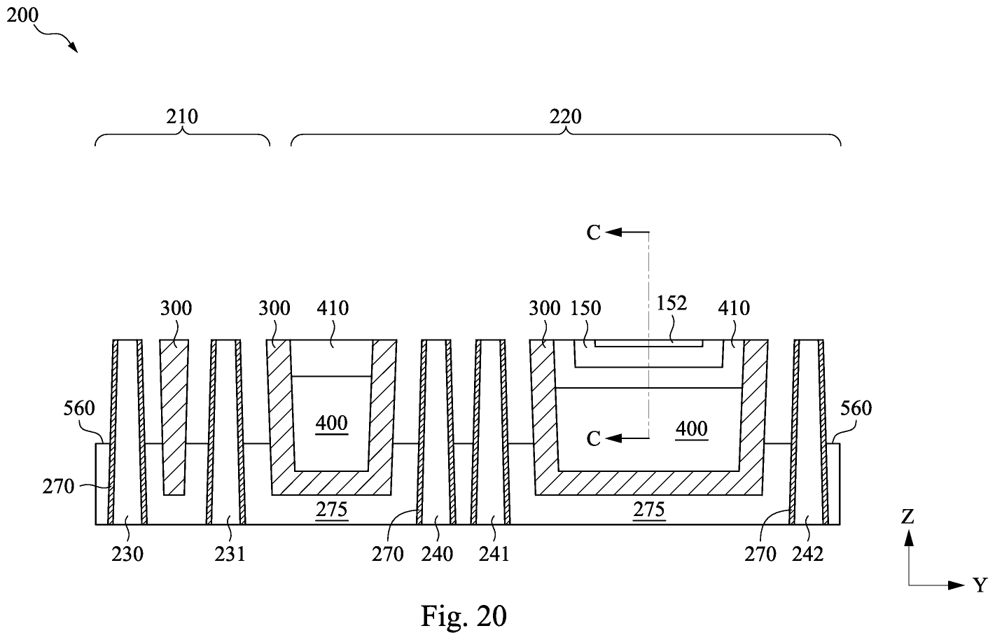

As shown in FIG. 20, an etching process is performed to recess the dielectric layer 275. In some embodiments, the etching process is performed such that an upper surface 560 of the remaining portion of the dielectric layer 275 is disposed substantially below an upper surface 570 of the fin structures 230-231 and 240-242.

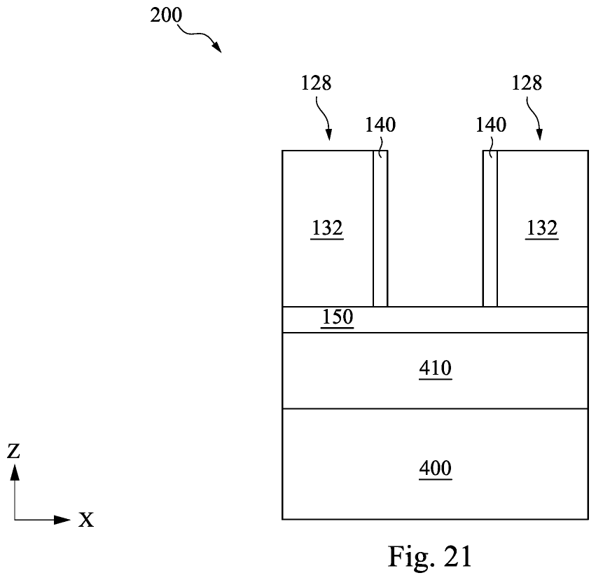

FIGS. 21-23 illustrate cross-sectional views of a portion of the semiconductor device structure 200 taken along line C-C′ of FIG. 20, in accordance with some embodiments. As shown in FIG. 21, the one or more sacrificial gate stacks 128 are formed on one or more portions of the fin structures 230-231, 240-242 and the high-k dielectric layer 150. In some embodiments, the dielectric material 152 disposed on the high-k dielectric layer 150 is removed during the patterning of the sacrificial gate stacks 128. The spacer 140 is formed on each sidewall of the sacrificial gate stacks 128, and the spacer 140 is disposed on the high-k dielectric layer 150, as shown in FIG. 21.

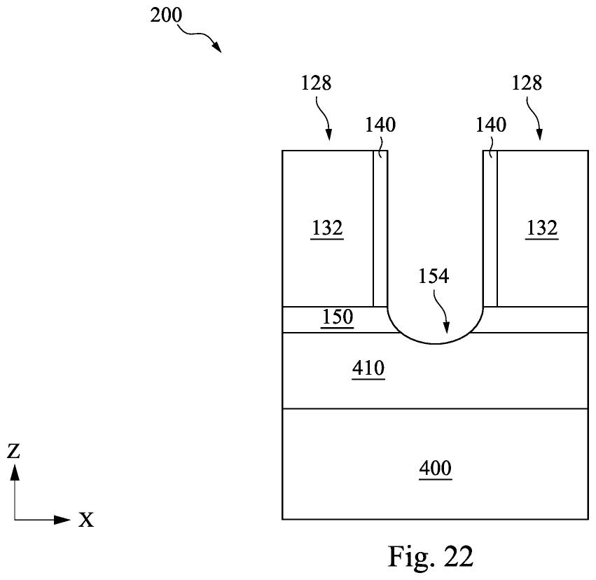

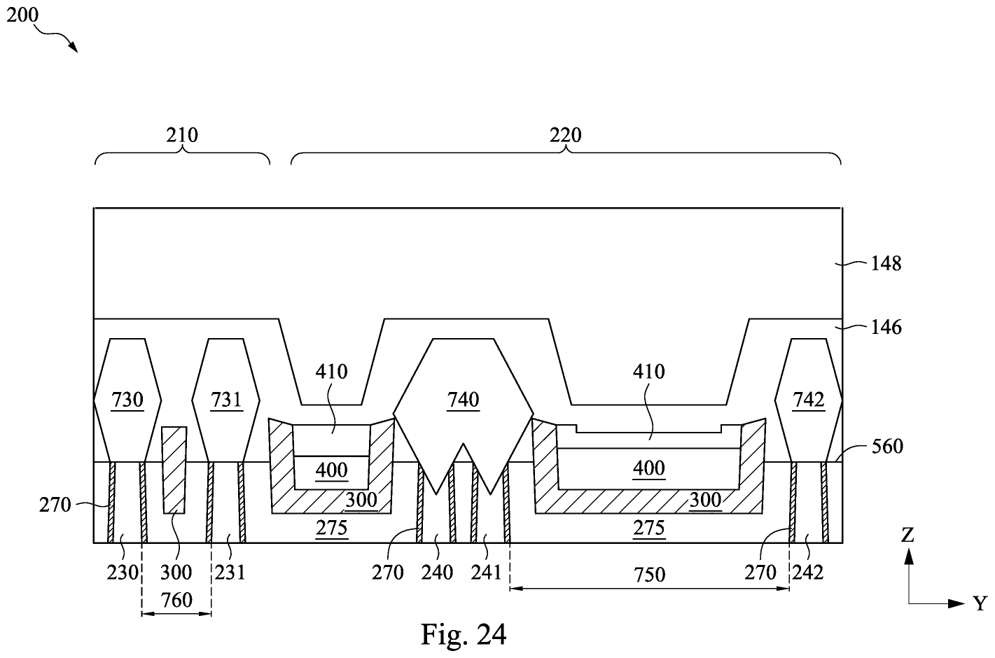

As shown in FIG. 22, an opening 154 is formed in the high-k dielectric layer 150. In some embodiments, the opening 154 extends into the dielectric material 410, as shown in FIG. 22. The opening 154 may be formed during the recessing the exposed portions of the fin structures 230-231 and 240-242 and during the formation of the S/D epitaxial features 730, 731, 740, 742 (FIG. 24). Unlike the opening 142 shown in FIG. 10, the opening 154 does not have the “keyhole” shaped cross-section, as the result of having the high-k dielectric layer 150, which is more etch resistant during the processes to recess the exposed portions of the fin structures 230-231 and 240-242 and during the formation of the S/D epitaxial features 730, 731, 740, 742 (FIG. 24).

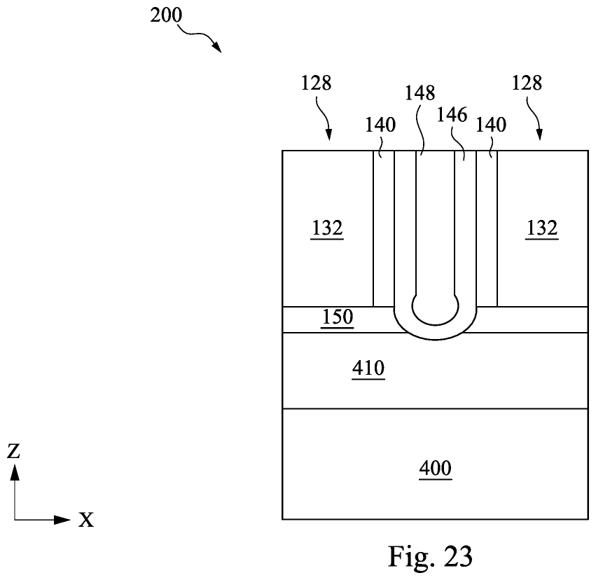

As shown in FIG. 23, the CESL 146 and the ILD layer 148 are formed in the opening 154. Because the opening 154 does not have the “keyhole” shaped cross-section, the CESL 146 and the ILD layer 148 may fill the opening 154 without a seam or void. As a result, leakage path is minimized.

FIG. 24 illustrates a cross-sectional side view of the semiconductor device structure 200 of FIG. 23, in accordance with some embodiments. FIG. 24 illustrates the S/D regions of the semiconductor device structure 200. As shown in FIG. 24, the portion of the high-k dielectric layer 150 not covered by the sacrificial gate stacks 128 is removed, and the CESL 146 is disposed on the S/D epitaxial features 730, 731, 740, 742, the dielectric layer 300, and the dielectric material 410. The dielectric layer 300 and the dielectric materials 400, 410 may be a hybrid fin or a dielectric fin.

In subsequent processes, conductive features (not shown) are formed in the ILD layer 148 and the CESL 146 to be electrically connected to the S/D epitaxial features 730, 731, 740, 742. In some embodiments, the process window for forming the openings in the ILD layer 148 and the CESL 146 may be large, such that the portions of the ILD layer 148 and the CESL 146 formed over the dielectric material 410 are removed. Because there is no seam or void in the dielectric material 410, the conductive features are not formed in the dielectric material 410. As a result, the formation of leakage path is substantially reduced.

The present disclosure in various embodiments provides a semiconductor device structure including a hybrid fin having multiple materials. Some embodiments may achieve advantages. For example, the hybrid fin may include a high-k dielectric layer 144, which has better gap fill capability compared to the material of a CESL 146. The high-k dielectric layer 144 is seamless and void-free. As a result, the formation of electrical leakage path is substantially reduced.

An embodiment is a semiconductor device structure. The structure includes a first source/drain (S/D) epitaxial feature disposed over a substrate, a second S/D epitaxial feature adjacent the first S/D epitaxial feature, and a hybrid fin disposed between the first and second S/D epitaxial features. The hybrid fin includes a first dielectric material, a second dielectric material disposed on the first dielectric material, a dielectric layer surrounding the first and second dielectric materials, and a high-k dielectric layer disposed in the first and second dielectric materials. The high-k dielectric layer has an upper surface located at a level between a level of an upper surface of the second dielectric material and a level of a lower surface of the second dielectric material.

Another embodiment is a method. The method includes forming first, second, third fin structures over a substrate, a first trench is formed between the first and second fin structures, and a second trench is formed between the second and third fin structures. The method further includes depositing a first dielectric layer in the first and second trenches, and the first dielectric layer fills the first trench. The method further includes depositing a first dielectric material on the first dielectric layer in the second trench, recessing the first dielectric material, depositing a second dielectric material on the first dielectric material in the second trench, and recessing a first portion of the first, second, third fin structures. An opening is formed in a first portion of the second dielectric layer during the recessing. The method further includes forming first, second, third source/drain (S/D) epitaxial features, and the opening is expanded in the first dielectric material during the forming the first, second, third S/D epitaxial features. The method further includes depositing a high-k dielectric layer in the opening and on the first, second, third S/D epitaxial features, and the high-k dielectric layer fills a portion of the opening in the first dielectric material. The method further includes removing portions of the high-k dielectric layer deposited on the first, second, third S/D epitaxial features.

A further embodiment is a method. The method includes forming first, second, third fin structures over a substrate and depositing a first dielectric layer. A first portion of the first dielectric layer is deposited between the first and second fin structures, and a second portion of the first dielectric layer is deposited between the second and third fin structures. The method further includes depositing a first dielectric material, a first portion of the first dielectric material is deposited on the first portion of the first dielectric layer, and a second portion of the first dielectric material is deposited on the second portion of the first dielectric layer. The method further includes depositing a second dielectric material, a first portion of the second dielectric material is deposited on the first portion of the first dielectric material, and a second portion of the second dielectric material is deposited on the second portion of the first dielectric material. The method further includes depositing a high-k dielectric layer, a first portion of the high-k dielectric layer is deposited on the first portion of the second dielectric material, and a second portion of the high-k dielectric layer is deposited on the second portion of the second dielectric material. The method further includes depositing a third dielectric material on the second portion of the high-k dielectric layer, performing a planarization process to remove the first portion of the high-k dielectric layer and a portion of the third dielectric material, forming one or more sacrificial gate stacks over a first portion of the first, second, third fin structures and over a first portion of the second portion of the high-k dielectric layer, forming spacers on sidewalls of the one or more sacrificial gate stacks and on second portions of the second portion of the high-k dielectric layer, forming an opening in a third portion of the second portion of the high-k dielectric layer, and depositing a contact etch stop layer in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain (S/D) epitaxial feature disposed over a substrate;
a second S/D epitaxial feature adjacent the first S/D epitaxial feature;
a hybrid fin disposed between the first and second S/D epitaxial features, wherein the hybrid fin comprises:
a first dielectric material;
a second dielectric material disposed on the first dielectric material;
a dielectric layer surrounding the first and second dielectric materials; and
a high-k dielectric layer disposed in the first and second dielectric materials, wherein the high-k dielectric layer has an upper surface located at a level between a level of an upper surface of the second dielectric material and a level of a lower surface of the second dielectric material.

2. The semiconductor device structure of claim 1, wherein the first dielectric material comprises an oxide.

3. The semiconductor device structure of claim 2, wherein the second dielectric material comprises SiN, SiCN, or SiOCN.

4. The semiconductor device structure of claim 3, wherein the dielectric layer comprises SiN, SiCN or SiOCN.

5. The semiconductor device structure of claim 4, wherein the second dielectric material and the dielectric layer comprise different materials.

6. The semiconductor device structure of claim 4, wherein the second dielectric material and the dielectric layer comprise a same material.

7. The semiconductor device structure of claim 4, wherein the high-k dielectric layer comprises hafnium oxide, zirconium oxide, zirconium aluminum oxide, hafnium aluminum oxide, hafnium silicon oxide, or aluminum oxide.

8. A method, comprising:
forming first, second, third fin structures over a substrate, wherein a first trench is formed between the first and second fin structures and a second trench is formed between the second and third fin structures;
depositing a first dielectric layer in the first and second trenches, wherein the first dielectric layer fills the first trench;
depositing a first dielectric material on the first dielectric layer in the second trench;
recessing the first dielectric material;
depositing a second dielectric material on the first dielectric material in the second trench;
recessing a first portion of the first, second, third fin structures, wherein an opening is formed in a first portion of the second dielectric layer during the recessing;
forming first, second, third source/drain (S/D) epitaxial features, wherein the opening is expanded in the first dielectric material during the forming the first, second, third S/D epitaxial features;
depositing a high-k dielectric layer in the opening and on the first, second, third S/D epitaxial features, wherein the high-k dielectric layer fills a portion of the opening in the first dielectric material; and
removing portions of the high-k dielectric layer deposited on the first, second, third S/D epitaxial features.

9. The method of claim 8, further comprising forming a contact etch stop layer on the high-k dielectric layer after the removing the portions of the high-k dielectric layer.

10. The method of claim 9, further comprising forming one or more sacrificial gate stacks over a second portion of the first, second, third fin structures prior to recessing the first portion of the first, second, third fin structures.

11. The method of claim 8, wherein the opening has a “keyhole” shaped cross-section after expanding in the first dielectric material.

12. The method of claim 10, further comprising depositing a second dielectric layer, wherein the first dielectric layer is deposited on the second dielectric layer.

13. The method of claim 12, further comprising recessing the second dielectric layer after depositing the second dielectric material and before forming the one or more sacrificial gate stacks.

14. The method of claim 8, wherein the high-k dielectric layer is deposited by an atomic layer deposition (ALD) process.

15. A method, comprising:
forming first, second, third fin structures over a substrate;
depositing a first dielectric layer, wherein a first portion of the first dielectric layer is deposited between the first and second fin structures, and a second portion of the first dielectric layer is deposited between the second and third fin structures;
depositing a first dielectric material, wherein a first portion of the first dielectric material is deposited on the first portion of the first dielectric layer, and a second portion of the first dielectric material is deposited on the second portion of the first dielectric layer;
depositing a second dielectric material, wherein a first portion of the second dielectric material is deposited on the first portion of the first dielectric material, and a second portion of the second dielectric material is deposited on the second portion of the first dielectric material;
depositing a high-k dielectric layer, wherein a first portion of the high-k dielectric layer is deposited on the first portion of the second dielectric material, and a second portion of the high-k dielectric layer is deposited on the second portion of the second dielectric material;
depositing a third dielectric material on the second portion of the high-k dielectric layer;
performing a planarization process to remove the first portion of the high-k dielectric layer and a portion of the third dielectric material;
forming one or more sacrificial gate stacks over a first portion of the first, second, third fin structures and over a first portion of the second portion of the high-k dielectric layer;
forming spacers on sidewalls of the one or more sacrificial gate stacks and on second portions of the second portion of the high-k dielectric layer;
forming an opening in a third portion of the second portion of the high-k dielectric layer; and
depositing a contact etch stop layer in the opening.

16. The method of claim 15, wherein the opening is in the second portion of the second dielectric material.

17. The method of claim 15, further comprising recessing a second portion of the first, second, third fin structures after forming the one or more sacrificial gate stacks.

18. The method of claim 17, further comprising forming first, second, third source/drain (S/D) epitaxial features, wherein the opening is formed during the recessing the second portion of the first, second, third fin structures and forming the first, second, third S/D epitaxial features.

19. The method of claim 18, further comprising forming an interlayer dielectric layer on the contact etch stop layer.

20. The method of claim 19, further comprising depositing a second dielectric layer, wherein the first dielectric layer is deposited on the second dielectric layer.
